(19) United States
(12) Patent Application Publication
(10) Pub. No.: US 2026/0129894 A1
(43) Pub. Date: May 7, 2026

(54) INTERFACIAL LAYER IN SEMICONDUCTOR DEVICES

(71) Applicant: Taiwan Semiconductor Manufacturing Company, Ltd., Hsinchu (TW)

(72) Inventors: Shen-Yang LEE, Miaoli (TW); Hsiang-Pi CHANG, New Taipei City (TW); Chun-Fu LU, Hsinchu (TW); Huang-Lin CHAO, Hsinchu City (TW); Pinyen LIN, Rochester, NY (US); Hsu-Kai CHANG, Hsinchu (TW); Kenichi SANO, Hsinchu (TW)

(73) Assignee: Taiwan Semiconductor Manufacturing Company, Ltd., Hsinchu (TW)

(21) Appl. No.: 18/934,615

(22) Filed: Nov. 1, 2024

(51) Int. Cl. H01L 29/775; H01L 21/02; H01L 21/28; H01L 29/06; H01L 29/423; H01L 29/66; H01L 29/786

(52) U.S. Cl. CPC H10D 30/43; H10D 30/014; H10D 30/024; H10D 30/6735; H10D 30/6757; H10D 62/121; H10D 64/0134; H10P 14/69215; H10P 14/69396; H10D 64/017

(57) ABSTRACT

This disclosure is directed to a method of improving a quality of an interfacial layer of a gate structure of a semiconductor device. The method includes forming a channel region on a substrate and oxidizing a surface of the channel region to form the interfacial layer including silicon oxide. The method further includes depositing a layer of metal oxide (e.g., yttrium oxide) on the interfacial layer, performing an annealing process to transform silicon oxide in the interfacial layer into silicon dioxide by reducing a density of oxygen vacancies in the interfacial layer, and removing the layer of metal oxide. The method further includes forming a high-k dielectric layer and a gate electrode on the interfacial layer to form the gate structure.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around field effect transistors (GAA FETs). Such scaling down has increased the complexity of semiconductor manufacturing processes.

### BRIEF DESCRIPTION OF THE DRAWINGS

Aspects of the present disclosure are best understood from the following detailed description when read with the accompanying figures. It is noted that, in accordance with the common practice in the industry, various features are not drawn to scale. In fact, the dimensions of the various features may be arbitrarily increased or reduced for clarity of illustration and discussion.

FIG. 1 is an isometric view of a semiconductor device including semiconductor transistors, in accordance with some embodiments.

FIG. 2 is a cross-sectional view of a semiconductor device including semiconductor transistors, in accordance with some embodiments.

FIG. 3 is an x-ray photoelectron spectroscopy (XPS) diagram of an interfacial layer of a semiconductor transistor, in accordance with some embodiments.

FIGS. 4A and 4B are flowcharts of a method for the formation of a semiconductor transistor, in accordance with some embodiments.

FIGS. 5 and 6 are isometric views of intermediate structures during the fabrication of a semiconductor transistor, in accordance with some embodiments.

FIGS. 7-19 are cross-sectional views of intermediate structures during the fabrication of a semiconductor transistor, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed that are between the first and second features, such that the first and second features are not in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “about” and “substantially” can refer to a percentage of the values as interpreted by those skilled in relevant art(s) in light of the teachings herein.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

By way of example and not limitation, nanostructure transistors, like GAA nano-sheet (NS) or nano-wire (NW) FETs (collectively referred to as “GAAFETs”) with nano-sheet (NS) or nano-wire (NW) channel regions, can be formed as follows. A fin-like structure with alternating silicon-germanium (SiGe) and silicon (Si) NS or NW layers is formed on a substrate (e.g., on semiconductor substrate). A sacrificial gate structure is then formed on a middle portion of the fin-like structure to cover top and sidewall surfaces of the fin-like structure so that edge portions of the fin-like structure are not covered by the sacrificial gate structure. The edge portions of the fin-like structure not covered by the sacrificial gate structure are removed. Subsequently, edge portions of the SiGe NS or NW layers are recessed with respect to edge portions of the Si NS or NW layers, and an inner spacer structure is formed by depositing a dielectric material to fill the space formed by the etched portions of the SiGe NS or NW layers. Source/drain (S/D) epitaxial structures are then formed to abut (or to be in contact with) edge portions of the fin-like structures so that the S/D epitaxial structures are in contact with the Si NS or NW layers and isolated (or separated) from the SiGe NS or NW layers by the inner spacer structures. Source/drain may refer to a source or a drain, individually or collectively dependent upon the context. In a subsequent operation, the sacrificial gate structure is removed to expose the top and sidewall surfaces of the fin-like structure. The SiGe NS or NW layers are selectively removed from the fin-like structure. During the selective removal process, the Si NS or NW layers and the inner spacer structures are not removed. Subsequently, a gate structure is formed to surround the Si NS or NW layers. Similar to the SiGe NS or NW layers prior to their selective removal, the gate structure is isolated (or separated) from the S/D epitaxial structures through the inner spacer structures. The gate structure includes an interfacial layer (IL) over the Si NS or NW layers, a gate dielectric layer on the IL, and a gate electrode including a suitable work function metal on the gate dielectric layer.

The structure of the GAAFETs may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

As semiconductor devices continue scaling down, in the exemplary GAAFET formed by the process described above, critical dimensions of the GAAFET, such as lengths/widths of the Si NS or NW layers as channels and of the metal gate structure, are shrinking. Highly sensitive to the scaling down process, the quality of the IL becomes increasingly critical to the electrical performance and reliability of the GAAFET. The IL can include silicon oxide (e.g., SiOₓ with x<2) by oxidizing surfaces of the Si NS or NW layers. Since a ratio of oxygen (O) atoms to Si atoms in SiOₓ can be less than 2, the IL can include oxygen vacancies as defects, which can behave as tunneling-assistant traps for leakage currents between the channels and the gate structure, impacting the electrical performance and causing degradation of the GAAFET. Increasing the thickness of the IL, as an approach opposite to scaling down, may suppress the leakage current, yet compromising the gate structure's efficacy of modulating the conductivity of the channels. In addition, it is difficult to control a growth rate of the IL during the process of increasing the thickness of the IL (e.g., a thermal process with oxygen radicals), affecting the uniformity of the IL and impacting its quality.

The embodiments described herein are directed to overcoming the challenges mentioned above. In some embodiments, a structure of a semiconductor device can include a gate structure and a channel layer. The gate structure can include an IL on the channel layer. The IL can include silicon dioxide (SiO₂) having a stoichiometric ratio of O atoms to Si atoms being about 2. With SiO₂ instead of SiOₓ in the IL, the integrity of the IL can be improved due to the absence of oxygen vacancies, and leakage currents between the channel layer and the gate structure can be effectively suppressed.

In some embodiments, a method of forming the structure can include forming the channel layer and forming the gate structure. Forming the gate structure can include forming the IL on the channel layer and forming a high-k dielectric layer and a gate electrode on the IL. Forming the IL can include forming a layer of SiOₓ on the channel layer, depositing a layer of metal oxide (e.g., yttrium oxide (Y₂O₃)) on the layer of SiOₓ, annealing the layer of metal oxide and the layer of SiOₓ to reduce a density of oxygen vacancies in the layer of silicon oxide, and removing the layer of metal oxide. In particular, during the annealing of the layer of metal oxide and the layer of SiOₓ, O atoms in the layer of metal oxide can diffuse into the layer of SiOₓ to replace the oxygen vacancies in the layer of SiOₓ, transforming the layer of SiOₓ into a layer of SiO₂ and improving the quality of the IL. In addition, the annealing process can also facilitate a formation of a silicate layer between the layer of metal oxide and the layer of SiOₓ due to the reaction between metal atoms of the layer of metal oxide and the Si atoms of the layer of SiOₓ. The silicate layer can subsequently be removed following the removal of the layer of metal oxide, reducing a thickness of the IL, which is consistent with the scaling down process and in contrast to the aforementioned approach of increasing the thickness of the IL to suppress the leakage current. This method of forming the IL can also be applied to the fabrication processes of other semiconductor transistors, such as planar MOSFETs and finFETs.

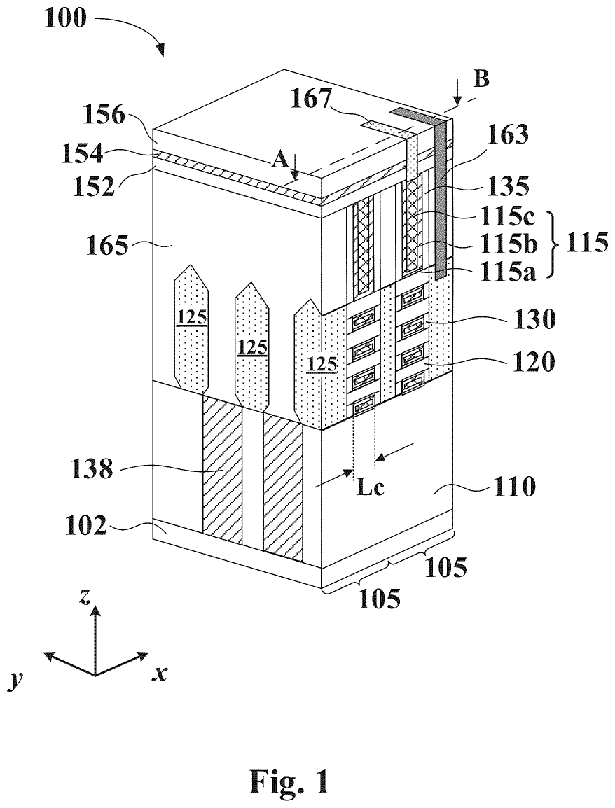

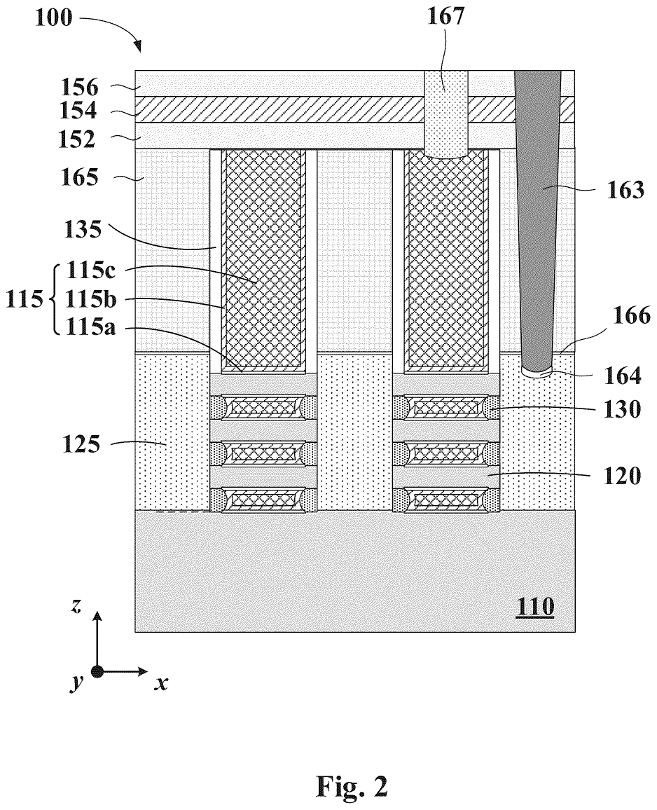

A semiconductor device 100 having multiple transistors 105 formed over a substrate 102 is described with reference to FIGS. 1 and 2, according to some embodiments. Semiconductor device 100 can be included in a microprocessor, memory cell, or other integrated circuit (IC). FIG. 1 illustrates an isometric view of semiconductor device 100. FIG. 2 illustrates cross-sectional (e.g., along the x-z plane) view of semiconductor device 100 along line A-B of FIG. 1.

Referring to FIG. 1, substrate 102 can be a semiconductor material, such as silicon. In some embodiments, substrate 102 can include a crystalline silicon substrate (e.g., wafer). In some embodiments, substrate 102 can include (i) an elementary semiconductor, such as silicon (Si) or germanium (Ge); (ii) a compound semiconductor including silicon carbide (SiC), gallium arsenide (GaAs), gallium phosphide (GaP), indium phosphide (InP), indium arsenide (InAs), and/or indium antimonide (InSb); (iii) an alloy semiconductor including silicon germanium carbide (SiGeC), silicon germanium (SiGe), gallium arsenic phosphide (GaAsP), gallium indium phosphide (InGaP), gallium indium arsenide (InGaAs), gallium indium arsenic phosphide (InGaAsP), aluminum indium arsenide (InAlAs), and/or aluminum gallium arsenide (AlGaAs); or (iv) a combination thereof. Further, substrate 102 can be doped depending on design requirements (e.g., p-type substrate or n-type substrate). In some embodiments, substrate 102 can be doped with p-type dopants (e.g., boron (B), indium (In), aluminum (Al), or gallium (Ga)) or n-type dopants (e.g., phosphorus (P), arsenic (As), or antimony (Sb)). In some embodiments, a crystal orientation of substrate 102 can be (100), (110), or (111).

Although FIGS. 1 and 2 show fin structure 110 accommodating two transistors 105, any number of transistors 105 can be disposed along fin structure 110. In some embodiments, transistors 105 can include multiple fin structures 110 extending along a first horizontal direction (e.g., in the x-direction) and gate structure 115 traversing through the multiple fin structures 110 along a second horizontal direction (e.g., in the y-direction). In some embodiments, a crystal orientation of fin structures 110 can be the same as the crystal orientation of substrate 102.

Referring to FIGS. 1 and 2, one or more nano-sheet (NS) layers 120 can be disposed over fin structure 110. Each NS layer 120 can be wrapped by gate structure 115 to function as transistor 105's channel. For example, a top surface, side surfaces, and a bottom surface of each NS layer 120 can be surrounded and in physical contact with gate structure 115. Fin structure 110 and NS layer 120 can be made of materials similar to (e.g., lattice mismatch within about 5%) substrate 102. In some embodiments, a crystal orientation of NS layer 120 can be the same as the crystal orientation of fin structures 110. In some embodiments, each of fin structure 110 and NS layer 120 can be made of Si or SiGe. Each of fin structure 110 and NS layer 120 can be un-doped, doped with p-type dopants, doped with n-type dopants, or doped with intrinsic dopants. In some embodiments, fin structure 110 and NS layers 120 can be doped together with p-type dopants or with n-type dopants. In some embodiments, a thickness of each of NS layers 120 can be between about 5 nm and about 10 nm. Although FIG. 1 shows that each transistor 105 includes four NS layers 120 and FIG. 2 shows that each transistor 105 includes three NS layers 120, any number of NS layers 120 can be included in each transistor 105. For example, each transistor 105 can include one, two, five, or six NS layers 120.

Referring to FIGS. 1 and 2, gate structures 115 can be a multilayered structure that wraps around each NS layer 120 to modulate transistor 105. Gate structures 115 can have a length Le representing transistor 105's channel length. Length Lc can have any suitable horizontal (e.g., in the x-direction) dimension, such as from about 3 nm to about 200 nm. In some embodiments, a height of gate structures 115 along a vertical direction (e.g., in the z-direction) above fin structure 110 can be between about 10 nm and about 20 nm. In some embodiments, the height of gate structures 115 above fin structure 110 can be greater than about 20 nm. In some embodiments, a thickness of gate structures 115 between adjacent NS layers 120 can be between about 5 nm and about 15 nm, corresponding the a spacing between adjacent NS layers 120. By way of example and not limitation, each gate structure 115 can include a dielectric stack formed by an IL 115a and a gate dielectric layer 115b. Further, each gate structure 115 can include a gate electrode 115c with capping layers, one or more work function metallic layers, and a metal fill not individually shown in FIG. 1 for simplicity. Gate dielectric layer 115b can include any suitable dielectric material with any suitable thickness that can provide channel modulation for transistor 105. In some embodiments, gate dielectric layer 115b can be made of a high-k dielectric material. For example, the high-k dielectric material can include hafnium oxide (HfO₂), aluminum oxide (Al₂O₃), scandium oxide (ScO₂), zirconium oxide (ZrO₂), calcium oxide (CaO), magnesium oxide (MgO), zirconium silicate (ZrSiO₄), or a combination thereof. In some embodiments, gate dielectric layer 115b can include lanthanum oxide (La₂O₃) on the high-k dielectric to form N-dipoles in gate dielectric layer 115b for tuning a threshold voltage of transistors 105. In some embodiments, a concentration of carbon atoms in gate dielectric layer 115b can be less than about 0.2%. In some embodiments, gate dielectric layer 115b can have a thickness ranging from about 1 nm to about 5 nm. Based on the disclosure herein, other materials and thicknesses for gate dielectric layer 115b are within the scope and spirit of this disclosure. Gate electrode 115c can function as a gate terminal for transistor 105. Gate electrode 115c can include any suitable conductive material that provides a suitable work function to modulate transistor 105. In some embodiments, gate electrode 115c can be made of titanium nitride, tantalum nitride, tungsten nitride, titanium, aluminum, copper, tungsten, tantalum, copper, or nickel. Based on the disclosure herein, other materials for gate electrode 115c are within the scope and spirit of this disclosure.

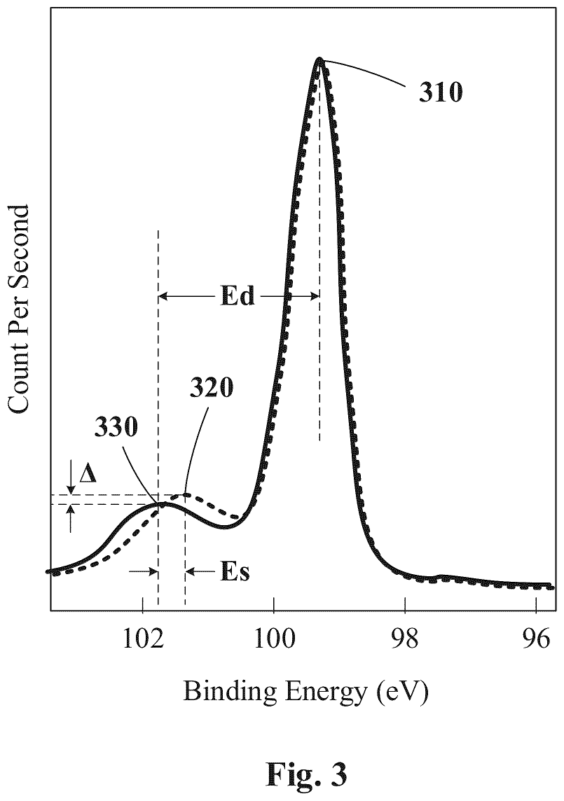

In some embodiments, a thickness of IL 115a can be between about 0.2 nm and about 2 nm. For example, the thickness of IL 115a can be about 1 nm. In some embodiments, IL 115a can include a layer of SiO₂ with a ratio of O atoms to Si atoms of about 2. As described below, the layer of SiO₂ can be formed by forming a layer of SiOₓ on NS layers 120, and then removing and/or reducing oxygen vacancies in the layer of SiOₓ to transform it into the layer of SiO₂. In some embodiments, IL 115a can be free of oxygen vacancies. In some embodiments, IL 115a can be free of Si dangling bonds, such that Si atoms in IL 115a are in an Si⁴⁺ valance state. In some embodiments, a difference between material compositions of the layer of SiO₂ and the layer of SiOₓ can be examined by x-ray photoelectron spectroscopy (XPS), as shown in FIG. 3. FIG. 3 shows a diagram including a solid curve and a dashed curve representing signals (in a unit of count per second) of photoemission electrons of the layer of SiO₂ and the layer of SiOₓ, respectively, as functions of the binding energy. In FIG. 3, both the solid curve and the dashed curve include a dominant peak 310 corresponding to photoemission from an Si⁰ state. In addition, both the solid curve and the dashed curve include satellite peaks 330 and 320, respectively, with satellite peak 330 blue-shifted from satellite peak 320 by an energy Es. In particular, satellite peak 320 corresponds to photoemission from Si³⁺, Si²⁺, and/or Si¹⁺ states, indicating that the layer of SiOₓ includes Si atoms with dangling bonds. On the other hand, satellite peak 330 corresponds to photoemission from Si⁴⁺ state that is fully covalence with deeper potential energy than Si³⁺, Si²⁺, or Si¹⁺ states, such that satellite peak 330 has a higher energy than satellite peak 320, indicating that the layer of SiO₂ is free of Si dangling bonds and oxygen vacancies. In some embodiments, energy Es can be between about 0.2 eV and about 0.8 eV. For example, energy Es can be about 0.5 eV. In some embodiments, an energy difference Ed between satellite peak 330 and dominant peak 310 can be about 3 eV. In some embodiments, satellite peak 330 can have an amplitude less than that of satellite peak 320 by a difference A, indicating that a thickness of the layer of SiO₂ is less than a thickness of the layer of SiOₓ. In some embodiments, a ratio of difference A and the amplitude of satellite peak 330 can be about 10%.

Referring to FIGS. 1 and 2, S/D epitaxial structures 125 can be disposed over opposite sides (e.g., along the x-direction) of each NS layer 120 to function as transistor 105's source and drain terminals. S/D epitaxial structures 125 can be disposed on fin structures 110. S/D epitaxial structure 125 can be made of an epitaxially-grown semiconductor material similar to (e.g., lattice mismatch within about 5%) NS layer 120. In some embodiments, S/D epitaxial structures 125 can be made of Si, Ge, SiGe, InGaAs, or GaAs. S/D epitaxial structures 125 can be doped with p-type dopants, n-type dopants, or intrinsic dopants. In some embodiments, S/D epitaxial structures 125 can have a different doping type from NS layer 120. In some embodiments, the n-type dopants in S/D epitaxial structure 125 can include P, As, Sb, or a combination thereof. In some embodiments, a crystal orientation of S/D epitaxial structure 125 can be the same as the crystal orientation of NS layer 120.

Referring to FIG. 2, semiconductor device 100 can include a dielectric layer 166 disposed over top surfaces of S/D epitaxial structures 125. As described below, dielectric layer 166 can be formed in the same process as forming IL 115a, when the top surfaces of S/D epitaxial structures 125 and surfaces of NS layer 120 are exposed to be oxidized to form a layer of SiOₓ, which subsequently undergoes the same treatment to IL 115a and is transformed into a layer of SiO₂. In some embodiments, dielectric layer 166 can have properties the same as or similar to IL 115a as described above and is not repeated for simplicity.

Referring to FIGS. 1 and 2, semiconductor device 100 can include inner spacer structures 130 abutting (or in contact with) side surfaces of gate structures 115. Inner spacer structures 130 can separate gate structures 115 from S/D epitaxial structures 125. For example, inner spacer structures 130 can be formed at gate structures 115's opposite sides along transistors 105's channel direction (e.g., along the x-direction) to separate gate structures 115 from S/D epitaxial structures 125. In some embodiments, inner spacer structures 130 can be formed between two vertically (e.g., in the z-direction) adjacent NS layers 120. In some embodiments, inner spacer structures 130 can be formed between fin structures 110 and NS layers 120. In some embodiments, inner spacer structures 130 can include a silicon-based dielectric, such as silicon nitride (SiN), silicon oxy-carbon-nitride (SiOCN), silicon carbon-nitride (SiCN), or silicon oxy-nitride (SiON). In some embodiments, inner spacer structures 130 can include a low-k material, such as a porous material and a carbon-rich silicon oxide based dielectrics.

Referring to FIGS. 1 and 2, semiconductor device 100 can further include gate spacers 135 formed between gate structure 115 and S/D epitaxial structure 125, which can provide structural support during the formation of gate structures 115. In addition, gate spacers 135 can provide gate structures 115 with electrical isolation and protection during the formation of S/D contacts. Gate spacers 135 can be made of any suitable dielectric material. In some embodiments, gate spacers 135 can be made of silicon oxide, silicon nitride, or a low-k material with a dielectric constant less than about 3.9. In some embodiments, gate spacers 135 can have any suitable thickness, such as between about 5 nm and about 15 nm. Based on the disclosure herein, other materials and thicknesses for gate spacers 135 are within the scope and spirit of this disclosure.

Referring to FIG. 1, semiconductor device 100 can further include shallow trench isolation (STI) regions 138 configured to provide electrical isolation between fin structures 110. STI regions 138 can also provide electrical isolation between transistor 105 and neighboring active and passive elements integrated with or deposited on substrate 102. STI regions 138 can include one or more layers of dielectric material, such as a nitride layer, an oxide layer disposed on the nitride layer, and an insulating layer disposed on the nitride layer. In some embodiments, the insulating layer can include silicon oxide, silicon nitride, silicon oxynitride, fluorine-doped silicate glass (FSG), a low-k dielectric material, and/or other suitable insulating materials. Based on the disclosure herein, other dielectric materials for STI regions 138 are within the scope and spirit of this disclosure.

Referring to FIGS. 1 and 2, semiconductor device 100 can further include interlayer dielectric (ILD) layers 165 to provide electrical isolation to structural elements it surrounds or covers, such as gate structures 115 and S/D epitaxial structures 125. In some embodiments, gate spacers 135 can be disposed between gate structures 115 and ILD layers 165. In some embodiments, ILD layers 165 can be disposed on S/D epitaxial structures 125 and dielectric layer 166. ILD layers 165 can include any suitable dielectric material to provide electrical insulation, such as silicon oxide, silicon dioxide, silicon oxycarbide, silicon oxynitride, silicon oxy-carbon nitride, and silicon carbonitride. ILD layers 165 can have any suitable thickness, such as from about 50 nm to about 200 nm, to provide electrical insulation. Based on the disclosure herein, other insulating materials and thicknesses for ILD layers 165 are within the scope and spirit of this disclosure.

Referring to FIGS. 1 and 2, semiconductor device 100 can further include dielectric layers 152, 154, and 156 on transistors 105. In some embodiments, dielectric layers 152, 154, and 156 can include silicon oxide and/or silicon nitride. For example, dielectric layers 152 and 156 can be layers of silicon oxide, and dielectric layers 154 can be a layer of silicon nitride. In some embodiments, dielectric layers 152, 154, and 156 can be etch stop layers.

Referring to FIGS. 1 and 2, semiconductor device 100 can further include S/D contacts 163 in contact with S/D epitaxial structures 125. S/D contacts 163 can be disposed on S/D epitaxial structures 125 and surrounded by ILD layers 165. In some embodiments, S/D contacts 163 can be disposed through dielectric layer 166. In some embodiments, S/D contacts 163 can be disposed through one or more of dielectric layers 152, 154, and 156. In some embodiments, silicide layers 164 can be disposed between S/D contacts 163 and S/D epitaxial structures 125. In some embodiments, a height of S/D contacts 163 can be between about 10 nm and about 50 nm. S/D contacts 163 can include any suitable conductive material that provides low contact resistance with S/D epitaxial structures 125. In some embodiments, S/D contacts 163 can be made of polysilicon, titanium nitride, tantalum nitride, tungsten nitride, titanium, aluminum, copper, tungsten, tantalum, nickel, or a combination thereof. Based on the disclosure herein, other materials for S/D contacts 163 are within the scope and spirit of this disclosure.

Referring to FIGS. 1 and 2, semiconductor device 100 can further include one or more gate contact vias 167 in contact with gate electrode 115c. Gate contact via 167 can be disposed on gate structures 115 and through one or more of dielectric layers 152, 154, and 156. In some embodiments, an interface between gate contact via 167 and gate electrode 115c can be substantially flat. In some embodiments, the interface between gate contact via 167 and gate electrode 115c can be curved. In some embodiments, a horizontal cross section of gate contact via 167 can have a rectangular shape or a cylindrical shape. In some embodiments, gate contact via 167 can have a tapered shape with a width of a top surface greater than a width of a bottom surface. In some embodiments, gate contact via 167 can have a uniform width from its top surface to its bottom surface. In some embodiments, the width of the top surface of gate contact via 167 can be between about 2 nm and about 40 nm. In some embodiments, the width of the bottom surface of gate contact via 167 can be between about 1 nm and about 40 nm. In some embodiments, a ratio of the width of the top surface of gate contact via 167 to the width of the bottom surface of gate contact via 167 can be between about 1 and about 3. In some embodiments, a height of gate contact via 167 can be between about 10 nm and about 50 nm. In some embodiments, an aspect ratio of gate contact via 167 can be between about 5:1 and about 20:1.

Although FIGS. 1 and 2 illustrate embodiments in which transistors 105 are GAAFETs, it should be understandable that IL 115a as described in FIGS. 1 and 2 can be applied to other types of transistors, such as MOSFETs, FinFETs, complementary fin field effect transistors (CFETs), or vertical fin field effect transistors (VFETs).

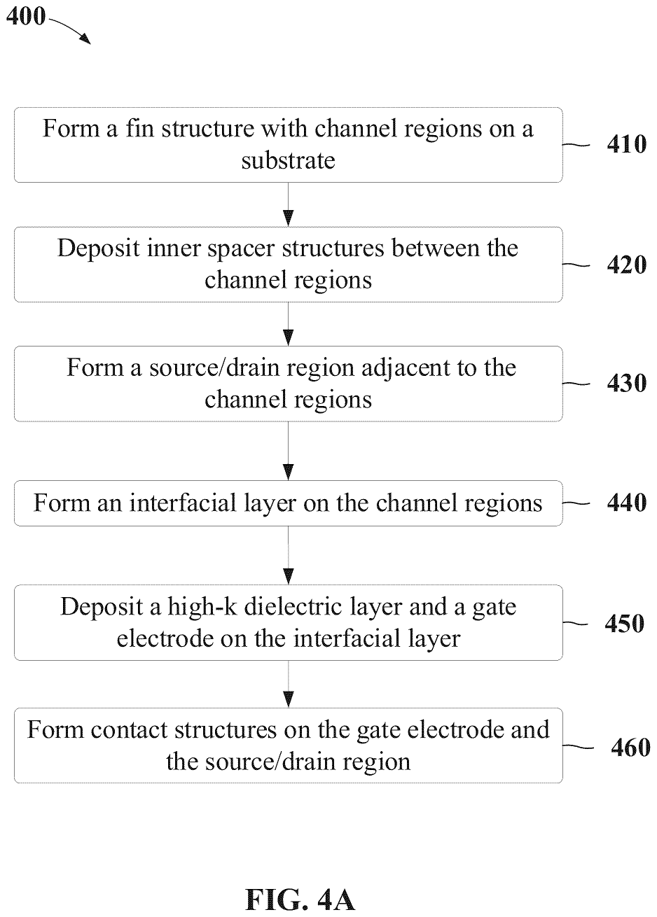

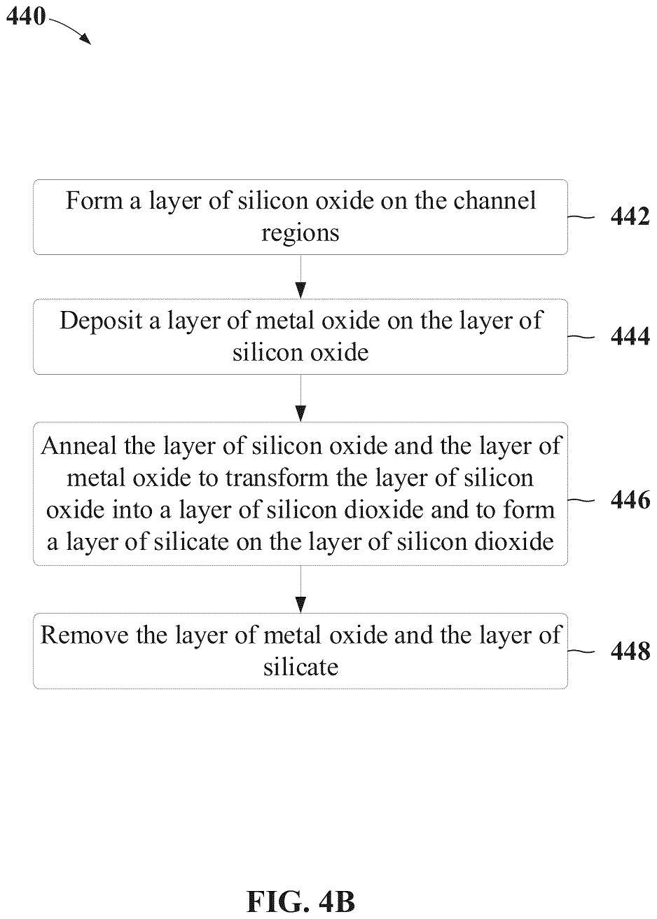

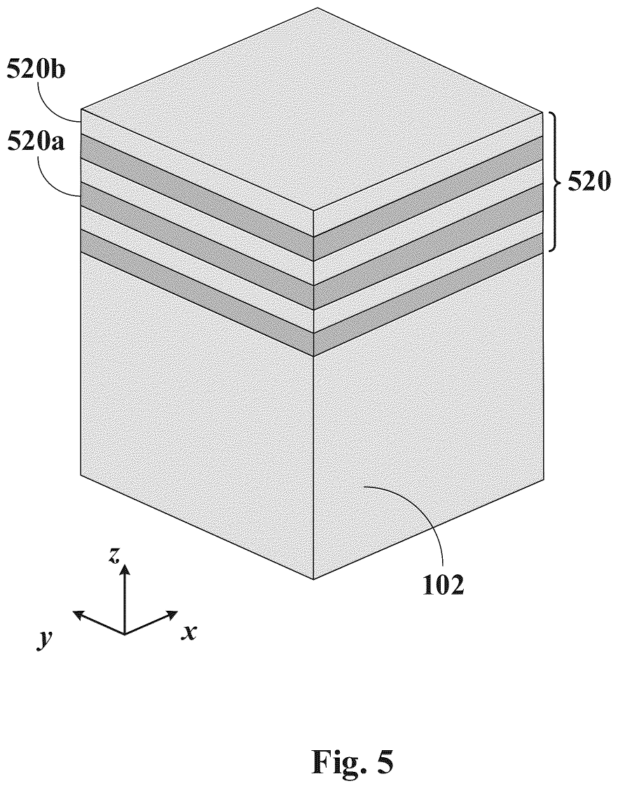

According to some embodiments, FIG. 4A illustrates a flowchart of a method 400 for the formation of transistors 105 shown in FIGS. 1 and 2. FIG. 4B illustrates a flowchart elaborating an operation 440 of fabrication method 400 and particularly about the formation of IL 115a of transistors 105. This disclosure is not limited to this operational description and additional operations may be performed. Other fabrication operations can be performed between the various operations of method 400 and are omitted merely for clarity. Moreover, not all operations may be needed to perform the disclosure provided herein. Additionally, some of the operations may be performed simultaneously, or in a different order than the ones shown in FIGS. 4A and 4B. In some embodiments, one or more other operations may be performed in addition to or in place of the presently described operations. For illustrative purposes, method 400 is described with reference to the structures shown in FIGS. 5-19. The discussion of elements in FIGS. 1 and 2 with the same annotations applies to FIGS. 5-19, unless mentioned otherwise.

Referring to FIG. 4A, method 400 begins with operation 410 and the process of forming a fin structure with channel regions on a substrate (e.g., substrate 102). In some embodiments, forming the fin structures can include forming a stack of alternating first and second NS layers on the substrate. FIG. 5 is an isometric view of substrate 102 and the formation of a stack 520 of alternating first and second NS layers 520a and 520b. In some embodiments, first and second NS layers 520a and 520b are formed on an exposed top surface of substrate 102. In some embodiments, first NS layers 520a are sacrificial NS layers subject to subsequent removal and second NS layers 520b correspond to NS layers 120 shown in FIG. 1. In some embodiments, the material of first NS layers 520a in stack 520 is selected so that first NS layers 520a can be selectively removed via etching from stack 520 without removing second NS layers 520b. For example, first NS layers 520a can be SiGe NS layers and second NS layers 520b can be Si NS layers.

First and second NS layers 520a and 520b can be grown with any suitable method. For example, first and second NS layers 520a and 520b can be grown with a chemical vapor deposition (CVD) process with precursor gases, like silane (SiH₄), disilane (Si₂H₆), dichlorosilane (SiH₂Cl₂), trichlorosilane (SiHCl₃), germane (GeH₄), digermane (Ge₂H₆), other suitable gases, or combinations thereof. In some embodiments, first NS layers 520a can include Ge with a concentration between about 20% and about 30%, while second NS layers 120 are substantially germanium-free e.g., have a Ge concentration less than about 1%. In some embodiments, second NS layers 520b, which correspond to NS layers 120 in FIG. 1, form the channel region of transistor 105 and can be lightly doped or intrinsic (e.g., un-doped). If lightly doped, the doping level of second NS layers 520b is less than about 10¹³ atoms/cm³. First and second NS layers 520a and 520b can be sequentially deposited without a vacuum break (e.g., in-situ) to avoid the formation of any intervening layers. In some embodiments, first NS layers 520a can be doped to increase their etching selectivity compared to second NS layers 520b in a subsequent etching operation.

In some embodiments, a thickness of first NS layers 520a controls the spacing between every other second NS layer 520b in stack 520. The thickness of first and second NS layers 520a and 520b can range, for example, from about 3 nm to about 15 nm. Since first and second NS layers 520a and 520b are grown individually, the thickness of each NS layer can be adjusted independently based, for example, on the deposition time. In some embodiments, additional or fewer number of first and second NS layers 520a and 520b can be formed in stack 520. In some embodiments, a total number of NS layers can be 2n, where n is the number of first NS layers 520a or the number of second NS layers 520b in stack 520. In some embodiments, n can be 1, 2, 3, 4, 5, 6, or any integer number greater than 6.

Referring to FIG. 4A, operation 410 can further include a process of patterning stack 520 to form the fin structures. In some embodiments, stack 520 is patterned to form the fin structures with a width along the y-direction and a length along the x-direction. The fin structures can be formed by patterning with any suitable method. For example, the fin structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. In some embodiments, a sacrificial layer is formed over stack 520 and patterned using a photolithography process. Spacers are formed alongside the patterned sacrificial layer using a self-aligned process. The sacrificial layer is then removed, and the remaining spacers may then be used as masking structures to pattern the fin structures.

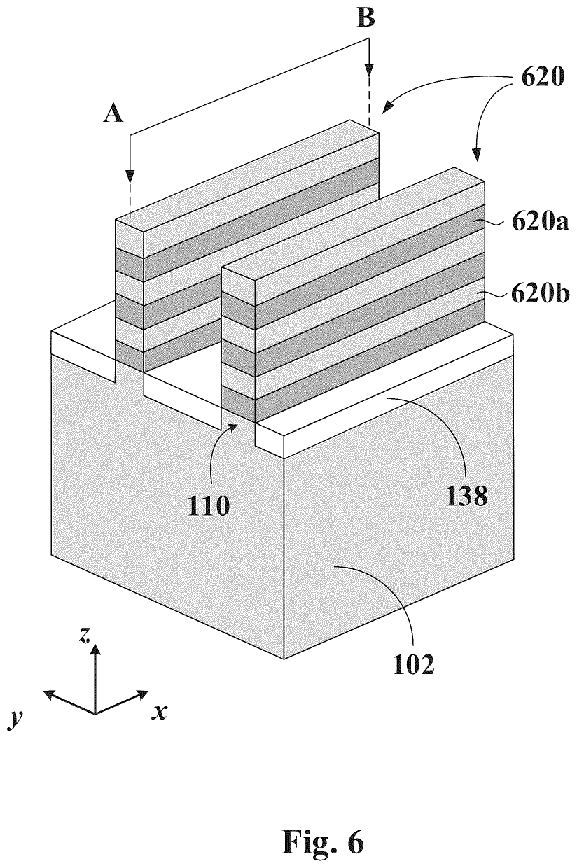

By way of example and not limitation, FIG. 6 is an isometric view of fin structures 620 formed from stack 520 with the aforementioned patterning process. In some embodiments, fin structures 620 can be formed by etching first and second NS layers 520a and 520b into first and second NS layers 620a and 620b. In some embodiments, the aforementioned patterning process does not terminate on the top surface of substrate 102 but continues to etch a top portion substrate 102 to form fin structures 110 from substrate 102 under fin structures 620. Since fin structures 620 and fin structures 110 are formed with the same patterning process, fin structures 620 and fin structures 110 are substantially aligned to each other. For example, sidewall surfaces of fin structures 620 in the x-z plane and y-z plane are substantially aligned to respective sidewall surfaces of fin structures 110 as shown in FIG. 6.

Additional fin structures, like fin structures 620, can be formed on substrate 102 in the same or different area of substrate 102. These additional fin structures are not shown in FIG. 6 for simplicity. By way of example and not limitation, each fin structure 620 has a width along the y-direction between about 15 nm and about 150 nm.

In some embodiments, NS layers 620a and 620b are referred to as “nano-sheets” when their width along the y-direction is substantially different from their height along z-direction—for example, when their width is larger/narrower than their height. In some embodiments, NS layers 620a and 620b can also be referred to as “nano-wires” when their width along the y-direction is substantially equal to their height along z-direction. In some embodiments, NS layers 620a and 620b are deposited as nano-sheets and subsequently patterned to form nano-wires with substantially equal height and width. By way of example and not limitation, NS layers 620a and 620b will be described in the context of nano-sheets (NS) layers. Based on the disclosure herein, nano-wires (NW) are within the spirit and the scope of this disclosure. Further, for example purposes and without limiting the scope of this disclosure, first and second NS layers 620a and 620b in method 400 will be described in the context of SiGe and Si NS layers, respectively.

In some embodiments, after the formation of fin structures 620, STI regions 138 can be formed on etched or recessed portions of substrate 102 to cover sidewall surfaces of fin structures 110. In some embodiments, STI regions 138 can electrically isolate fin structures 110 and include one or more silicon oxide based dielectrics. By way of example and not limitation, STI regions 138 can be formed as follows. An isolation structure material (e.g., a silicon oxide based dielectric) is blanket deposited over fin structures 620 and substrate 102. The as-deposited isolation structure material is planarized (e.g., with a chemical mechanical polishing (CMP) process) so that the top surface of the isolation structure material is substantially coplanar with the top surface of fin structures 620. The planarized isolation structure material is subsequently etched back so that the resulting STI regions 138 has a height substantially similar to fin structures 110, as shown in FIG. 6.

In some embodiments, fin structures 620 protrudes from STI regions 138 so that STI regions 138 does not cover sidewall portions of fin structures 620 as shown in FIG. 6.

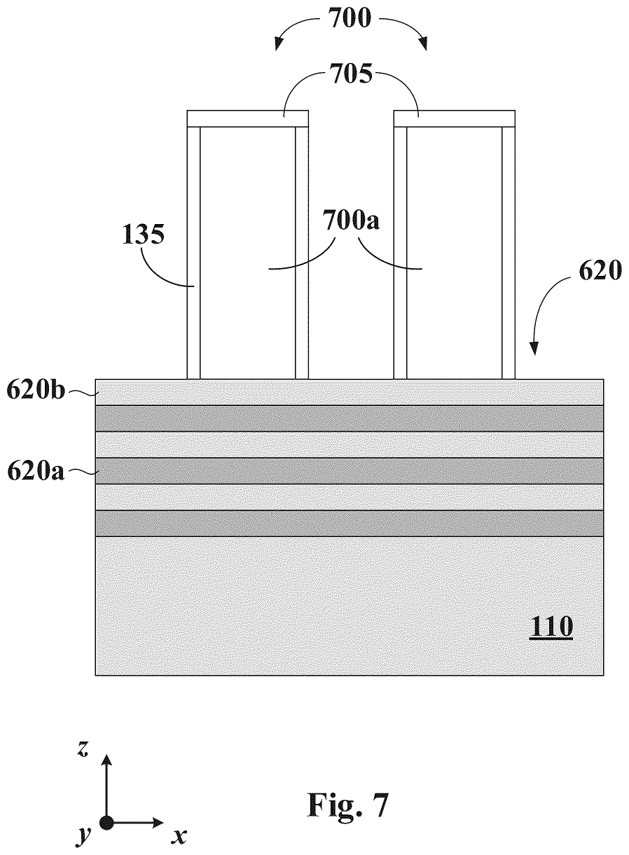

Referring to FIG. 4A, operation 410 can further include a process of forming a sacrificial gate structure on the fin structure. For example, sacrificial gate structures 700 can be formed on fin structures 620, as described with reference to FIG. 7. In some embodiments, sacrificial gate structures 700 are formed with their length along the y-direction—e.g., perpendicular to fin structures 620 shown in the isometric view of FIG. 6—and their width along the x-direction. By way of example and not limitation, FIG. 7 is a cross-sectional view of FIG. 6 along cut-line AB. FIG. 7 shows sacrificial gate structures 700 formed on portions of fin structures 620. Because FIG. 7 is a cross-sectional view, as opposed to an isometric view, portions of sacrificial gate structures 700 covering sidewall portions of fin structures 620 are not shown. Further, in the cross-sectional view of FIG. 7, only one of fin structures 620 from FIG. 6 is shown. In some embodiments, portions of sacrificial gate structures 700 are formed between fin structures 620 and on STI regions 138 shown in FIG. 6.

In some embodiments, sacrificial gate structures 700 can cover top and sidewall portions of fin structures 620. Sacrificial gate structures 700 are subsequently replaced with gate structures 115 shown in FIG. 1 during a subsequent gate replacement process. Sacrificial gate structures 700 can include a sacrificial gate electrode 700a formed on a sacrificial gate dielectric not shown in FIG. 7 for simplicity. Sacrificial gate structures 700 can also include capping layers 705 formed on top surfaces of sacrificial gate structures 700. In some embodiments, capping layers 705 can protect sacrificial gate electrode 700a from subsequent etching operations. At this fabrication stage, gate spacers 135 can be formed on side surfaces of sacrificial gate structures 700. As discussed above, gate spacers 135 are not removed during the gate replacement process; instead, gate spacers 135 facilitate the formation of gate structures 115 as shown in FIG. 1.

By way of example and not limitation, sacrificial gate structures 700 can be formed by depositing and patterning sacrificial gate electrode 700a over fin structures 620. In some embodiments, sacrificial gate structures 700 are formed over multiple fin structures 620. As shown in FIG. 7, portions of fin structures 620 are not covered by sacrificial gate structures 700. This is because the width of sacrificial gate structures 700 is narrower than the length of fin structures 620 along the x-direction. In some embodiments, sacrificial gate structures 700 are used as masking structures in subsequent etching operations to define the channel region of transistors 105 shown in FIG. 1. For this reason, the lateral dimensions (e.g., the width and length) of sacrificial gate structures 700 and gate structures 115 are substantially similar.

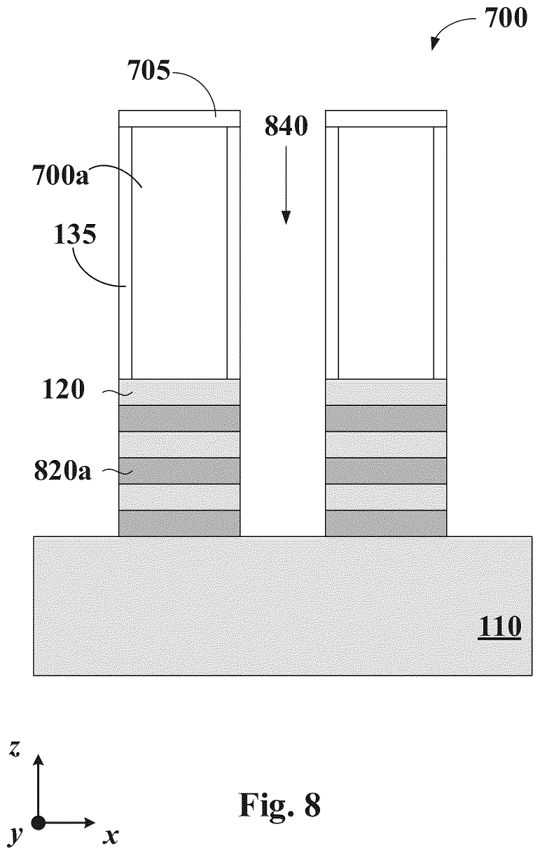

Referring to FIG. 4A, operation 410 can further include a process of removing portions of the fin structure exposed by the sacrificial gate structure, as described with reference to FIG. 8. Referring to FIG. 8, portions of fin structures 620 not covered by sacrificial gate structures 700 can be removed. In some embodiments, the removal process involves a dry etching process, a wet etching process, or combinations thereof. The removal process is selective towards first NS layers 620a and second NS layers 620b, shaping them into first NS layers 820a and NS layers 120, respectively. The removal process can further remove portions of fin structure 110. In some embodiments, the dry etching process includes etchants having an oxygen-containing gas, a fluorine-containing gas (e.g., carbon tetrafluoride (CF₄), sulfur hexafluoride (SF₆), difluoromethane (CH₂F₂), trifluoromethane (CHF₃), and/or hexafluoroethane (C₂F₆)); a chlorine-containing gas (e.g., chlorine (Cl₂), chloroform (CHCl₃), carbon tetrachloride (CCl₄), and/or boron trichloride (BCl₃)); a bromine-containing gas (e.g., hydrogen bromide (HBr) and/or bromoform (CHBr₃)); an iodine-containing gas; other suitable etching gases and/or plasmas; or combinations thereof. The wet etching chemistry can include diluted hydrofluoric acid (DHF), potassium hydroxide (KOH) solution, ammonia; a solution containing hydrofluoric acid (HF), nitric acid (HNO₃), acetic acid (CH₃COOH); or combinations thereof.

In some embodiments, the etchants of the aforementioned etching process do not substantially etch sacrificial gate structures 700—which is protected by capping layers 705 and gate spacers 135—and STI regions 138 shown in FIG. 6. This is because capping layers 705, gate spacers 135, and STI regions 138 include materials with a low etching selectivity, such as a silicon nitride based material (e.g., silicon nitride, silicon carbon nitride, and silicon carbon oxy-nitride) or silicon oxide based materials. In some embodiments, STI regions 138 shown in FIG. 6 are used as an etch stop layer for the etching process described above.

After removing the portions of fin structures 620 not covered by sacrificial gate structures 700, openings 840 are formed in each fin structure 620 as shown in FIG. 8. Openings 840 divide each fin structure 620 into separate portions, with each portion covered by a sacrificial gate structure 700. Each portion can include a stack of first NS layers 820a as sacrificial layers and NS layers 120 as channel regions.

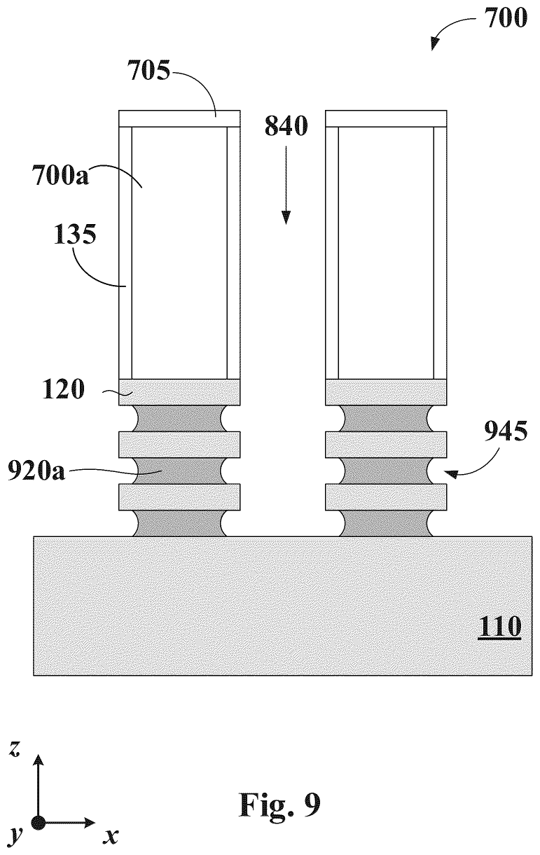

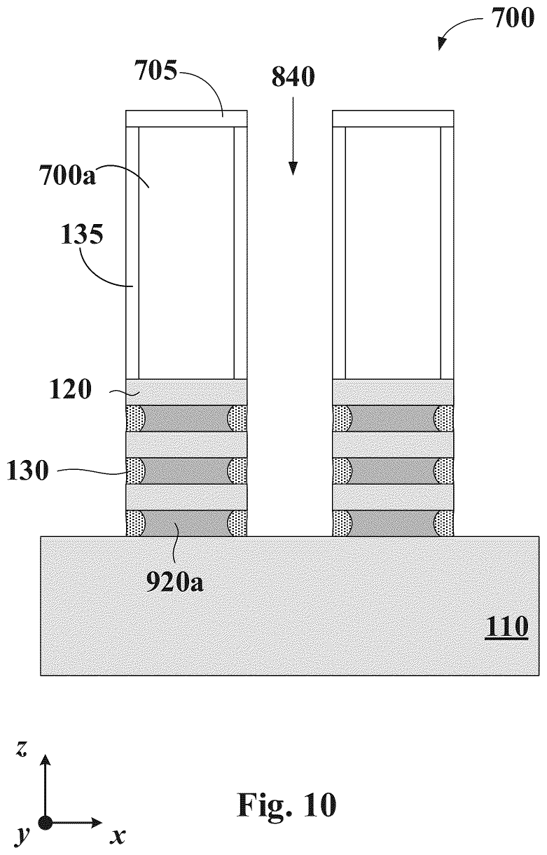

Referring to FIG. 4A, method 400 can continue with operation 420, in which inner spacer structures are formed between the channel regions. For example, as described with reference to FIGS. 9 and 10, inner spacers structures 130 can be formed in openings 840. The process of forming inner spacers can include (i) selectively etching edge portions of first NS layers 820a to form recess structures 945, as described with reference to FIG. 9 and (ii) forming inner spacer structures 130 in recess structures 945, as described with reference to FIG. 10. According to some embodiments, FIG. 9 shows the structure of FIG. 8 after exposed edges of first NS layers 820a are laterally etched (e.g., recessed) along the x-direction and turned into first NS layers 920a. According to some embodiments, exposed edges of first NS layers 820a are recessed (e.g., partially etched) by an amount that ranges from about 3 nm to about 10 nm along the x-direction as shown in FIG. 9 to form recesses structures 945.

In some embodiments, the selective etching of first NS layers 820a can be achieved with a dry etching process selective towards SiGe. For example, halogen-based chemistries exhibit a high etching selectivity towards Ge and a low etching selectivity towards Si. Therefore, halogen gases etch Ge-containing layers, such as first NS layers 820a, at a higher etching rate than substantially Ge-free layers like NS layers 120. In some embodiments, the halogen-based chemistries include fluorine-based and/or chlorine-based gasses. Alternatively, a wet etching chemistry with high selectivity towards SiGe can be used. By way of example and not limitation, a wet etching chemistry may include a mixture of sulfuric acid (H₂SO₄) and hydrogen peroxide (H₂O₂) (SPM), or a mixture of ammonia hydroxide with H₂O₂ and water (APM). The aforementioned etching processes are timed so that the desired amount of SiGe is removed.

In some embodiments, first NS layers 820a with a higher Ge atomic concentration have a higher etching rate than NS layers 120 with a lower or zero Ge atomic concentration. Therefore, the etching rate of the aforementioned etching processes can be adjusted by modulating the Ge atomic concentration (e.g., the Ge content) in first NS layers 820a. As discussed above, the Ge content in first NS layers 820a can range between about 20% and about 30%. A SiGe nano-sheet layer with about 20% Ge can be etched slower than a SiGe nano-sheet layer with about 30% Ge. Consequently, the Ge concentration can be adjusted accordingly to achieve the desired etching rate and selectivity between first NS layers 820a and NS layers 120.

Referring to FIGS. 9 and 10, once recessed structures 945 are formed, a dielectric layer can be blanket deposited over the entire structure of FIG. 9, and the portion of the dielectric layer outside recess structures 945 can be removed, leaving inner spacer structures 130 behind filling recessed structures 945, as described with reference to FIG. 10.

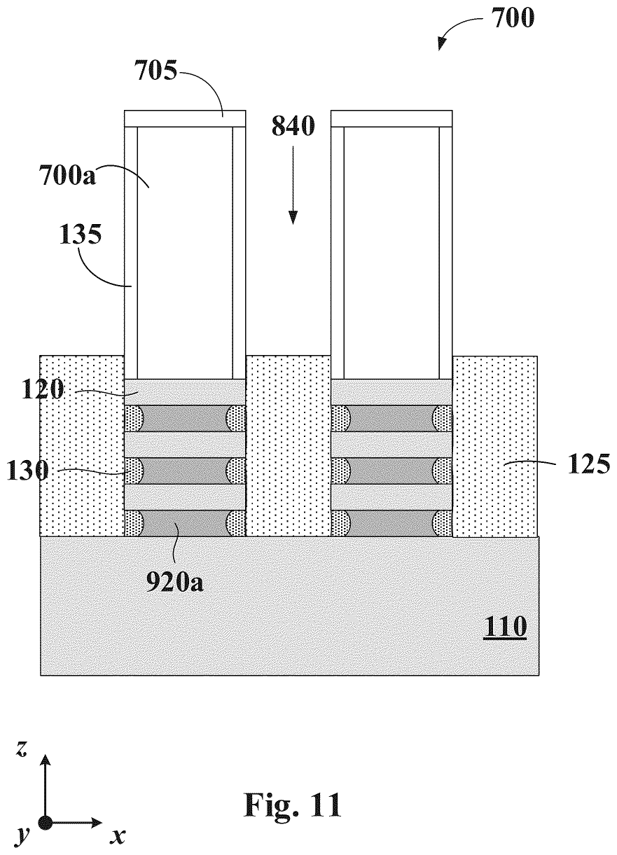

Referring to FIGS. 4A, method 400 can continue with operation 430, in which a source/drain (S/D) region is formed adjacent to the channel regions. For example, as described with reference to FIG. 11, S/D epitaxial structures 125 can be formed by epitaxially growing a semiconductor material in openings 840 and adjacent to NS layers 120.

In some embodiments, as described with reference to FIG. 11, S/D epitaxial structures 125 can be epitaxially grown with a CVD process similar to the one used in operation 405 to form first and second NS layers 520a and 520b, as described with reference to FIG. 5. In some embodiments, S/D epitaxial structures 125 can be epitaxially grown on side surfaces of second NS layers 120 in a horizontal direction (e.g., along the x-axis). In some embodiments, S/D epitaxial structures 125 can be epitaxially grown on top surfaces of fin structure 110 in a vertical direction (e.g., along the z-axis). In some embodiments, S/D epitaxial structures 125 can be grown using a plasma-enhanced CVD (PECVD) process. In some embodiments, precursor gases (e.g., SiH₄, SiH₂Cl₂, SiHCl₃, or a combination thereof) can be used to grow a semiconductor material (e.g., Si) having a crystalline structure the same as or similar to the crystalline structure of NS layers 120. In some embodiments, etching gases (e.g., hydrogen chloride (HCl)) can be used to selectively remove the semiconductor material with an amorphous structure formed on dielectric surfaces (e.g., side surfaces of inner spacer structures 130 and gate spacers 135. Removing the semiconductor material with the amorphous structure can ensure that the crystal structure of S/D epitaxial structures 125 is crystalline. In some embodiments, dopant precursor gases, such as phosphanes (PH₃), arsanes (AsH₃), stibane (SbH₃), or a combination thereof can be used in the CVD process or the PECVD process to dope S/D epitaxial structures 125.

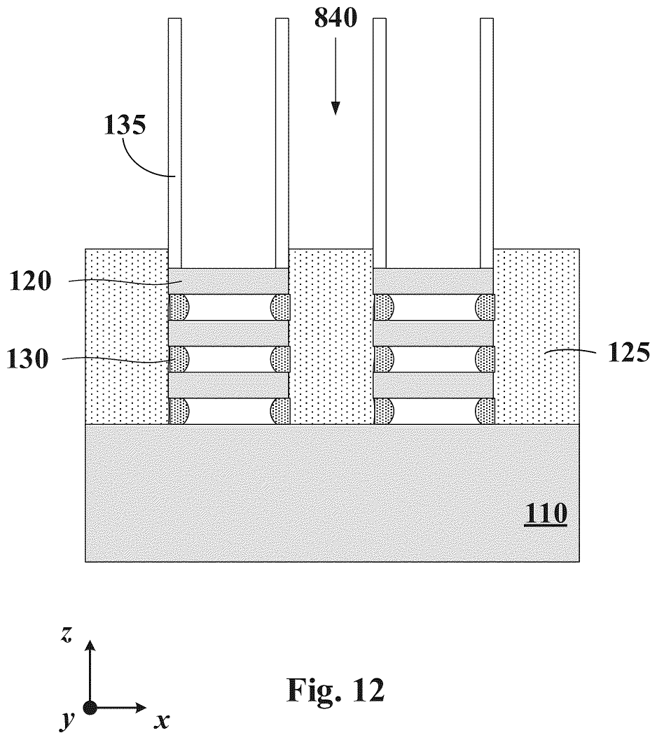

Referring to FIG. 4A, method 400 can continue with operation 440, in which an IL is formed on the channel regions. Prior to forming the IL, surfaces of the channel regions can be exposed by removing sacrificial gate structures 700 and first NS layers 920a, as described with reference to FIG. 12. In some embodiments, removing sacrificial gate structures 700 can include removing capping layer 705 to expose sacrificial gate electrode 700a and subsequently removing sacrificial gate electrode 700a to expose fin structures 620 between S/D epitaxial structures 125. In some embodiments, removing first NS layers 920a can include selectively etching first NS layers 920a without removing NS layers 120 as described with reference to FIG. 12.

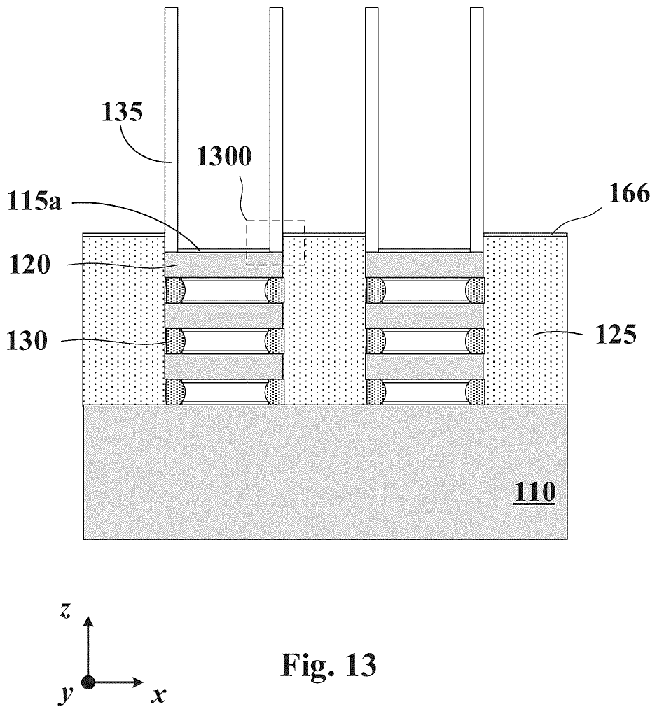

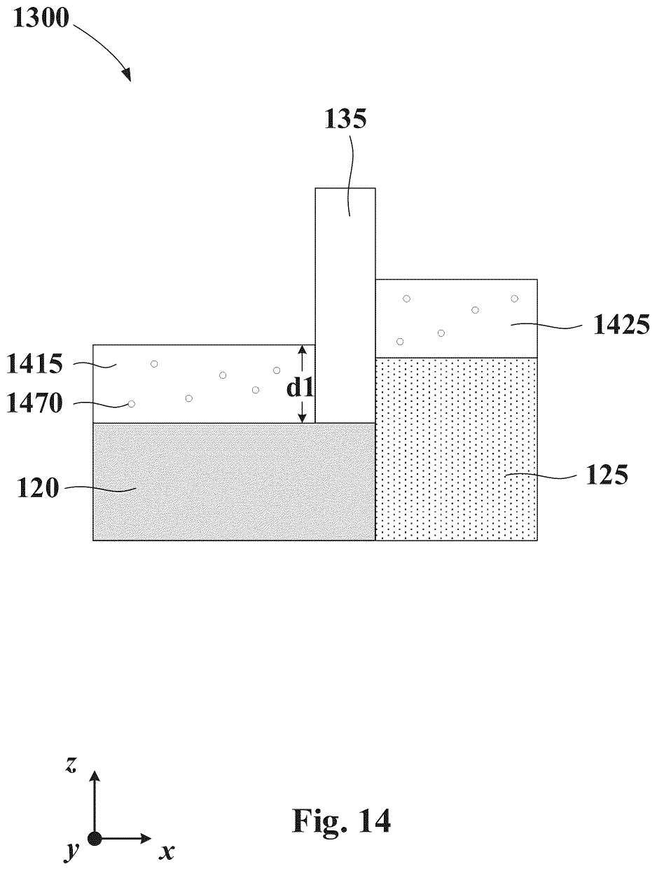

After exposing the surfaces of the channel regions, the IL can be formed on the channel regions. For example, as described with reference to FIG. 13, IL 115a can be formed on exposed surfaces of NS layers 120. Accompanying the formation of IL 115a, dielectric layer 166 can be formed on exposed top surfaces of S/D epitaxial structures 125. Operation 440 is further elaborated in FIG. 4B with reference to FIGS. 14-17 about a zoom-in region 1300 as shown in FIG. 13.

Referring to FIG. 4B, operation 440 starts with operation 442 of forming a layer of SiOₓ on the channel regions. For example, as described with reference to FIG. 14, a layer of SiOₓ 1415 can be formed on NS layers 120. In some embodiments, layer of SiOₓ 1415 can be formed by exposing the surfaces of NS layers 120 to a chemical solution, such as deionized water (DI-water), carbonated DI-water (DICO₂), ozonated DI-water (DIG₃), hydrogen peroxide (H₂O₂), sulfuric acid (H₂SO₄), chloric acid (HCl), ammonia (NH₄OH), or a combination thereof. In some embodiments, the chemical solution can be heated with a temperature beyond room temperature. For example, the temperature of the chemical solution can be about 50° C. In some embodiment, Si atoms at the surfaces of NS layers 120 can be oxidized by the chemical solution to form layer of SiOₓ 1415. The oxidation of Si atoms at the surfaces of NS layers 120 by exposing the surfaces of NS layers 120 to the chemical solution is incomplete, such that layer of SiOₓ 1415 includes Si atoms in Si³⁺, Si²⁺, or Si¹⁺ states with dangling bonds corresponding to oxygen vacancies 1470. In some embodiments, the oxidation of Si atoms at the surfaces of NS layers 120 can form layer of SiOₓ 1415 with a thickness d1 between about 0.2 nm and about 2 nm. The presence of layer of SiOₓ 1415 over the surfaces of NS layers 120 can prevent further oxidation into NS layers 120. In some embodiments, top surfaces of S/D epitaxial structures 125 can also be exposed to the chemical solution, and Si atoms at the top surfaces of S/D epitaxial structures 125 can also be oxidized to form a dielectric layer 1425 on S/D epitaxial structures 125, similar to the process that layer of SiOₓ 1415 is formed. In some embodiments, dielectric layer 1425 can have a chemical composition the same as or similar to that of layer of SiOₓ 1415. For example, dielectric layer 1425 can also include SiOₓ. In some embodiments, dielectric layer 1425 can have a thickness the same as or similar to that of layer of SiOₓ 1415.

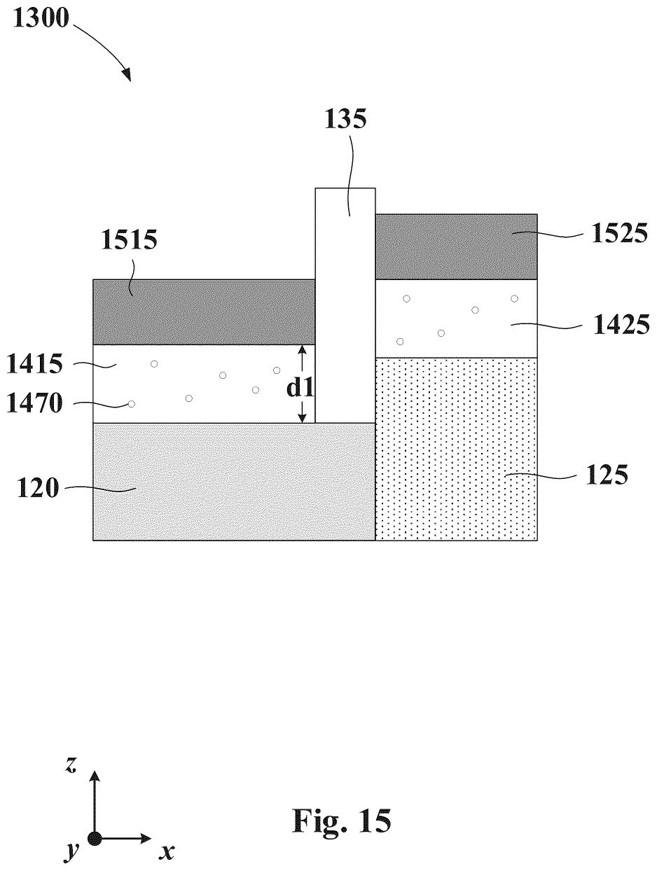

Referring to FIG. 4B, operation 440 continues with operation 444 of depositing a layer of metal oxide on the layer of SiOₓ. For example as described with reference to FIG. 15, a layer of metal oxide 1515 can be deposited on layer of SiOₓ 1415. In some embodiments, depositing layer of metal oxide 1515 can include depositing a metal oxide material with a metal element in group III of the periodic table, such as yttrium (Y), scandium (Sc), lutetium (Lu), lanthanum (La), lanthanides, strontium (Sr), zinc (Zn), and/or a combination thereof. For example, depositing layer of metal oxide 1515 can include depositing yttrium oxide (Y₂03). In some embodiments, the metal oxide material can also include zinc (Zn). In some embodiments, layer of metal oxide 1515 can be deposited by an atomic layer deposition (ALD) process or a chemical vapor deposition (CVD) process to cover exposed surfaces of layer of SiOₓ 1415 in a conformal manner. In some embodiments, during the deposition process, a thickness of layer of metal oxide 1515 can be controlled to be between about 5 nm and about 20 nm. In some embodiments, together with the deposition of layer of metal oxide 1515, a layer of metal oxide 1525 can also be deposited on dielectric layer 1425. Layer of metal oxide 1515 and layer of metal oxide 1525 can have the same or similar chemical composition and thickness.

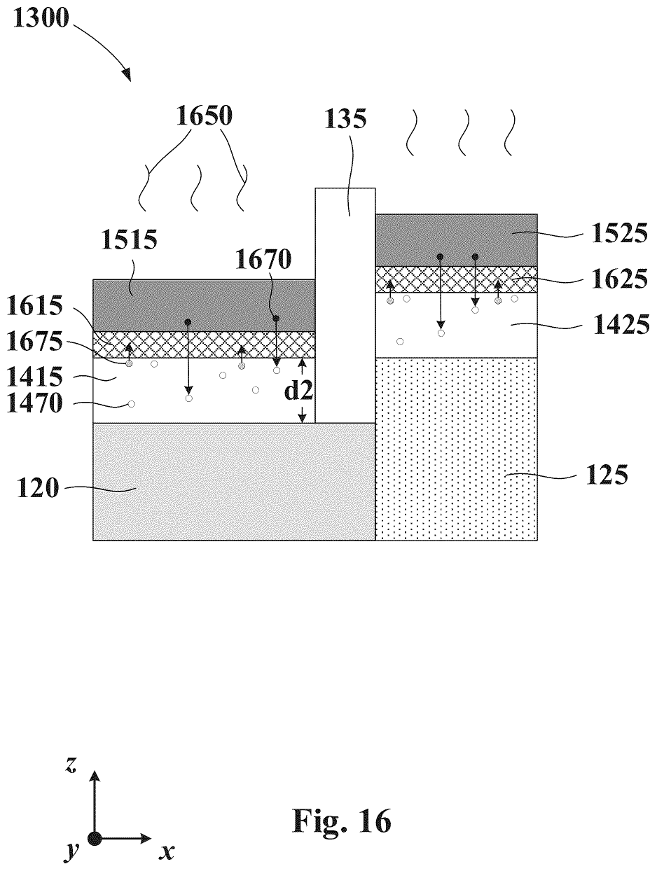

Referring to FIG. 4B, operation 440 continues with operation 446 and a process of annealing the layer of metal oxide and the layer of SiOₓ. Such an annealing process can transform the layer of SiOₓ into a layer of SiO₂. The annealing process can also form a layer of silicate between the layer of SiO₂ and the layer of metal oxide. For example, as described with reference to FIG. 16, an annealing process 1650 can promote oxygen atoms in layer of metal oxide 1515 to diffuse into layer of SiOₓ 1415 and replace oxygen vacancies 1470 by bonding with Si atoms in Si³⁺, Si²⁺, or Si¹⁺ states. By controlling parameters of annealing process 1650, such as a temperature and a duration, oxygen vacancies 1470 in layer of SiOₓ 1415 can be adequately reduced or removed to transform layer of SiOₓ 1415 into IL 115a with SiO₂, thus improving a quality of IL 115a. In some embodiments, the temperature of annealing process 1650 can be between about 450° C. and about 700° C. In some embodiments, the duration of annealing process 1650 can be between about 10 sec and about 60 sec.

In some embodiments, metal oxide 1515 can react with the Si atoms 1675 close to the surface of layer of SiOₓ 1415 (or its transformation of SiO₂) to form a silicate layer 1615. For example, Y₂O₃ of metal oxide 1515 can react with SiOₓ under the equation Y₂O₃+SiOₓ→Y₂(SiOₓ)+3O and release an energy of about 53±5 kJ/mol. The energy released in the reaction can further promote extra oxygen atom produced in the reaction to diffuse into layer of SiOₓ 1415 and reduce a population of oxygen vacancies 1470. The consumed SiOₓ in the reaction can reduce the thickness of layer of SiOₓ 1415 to d2. In some embodiments, a thickness reduction Δd (a difference between thicknesses d1 and d2) can be about 0.1 nm. In some embodiments, a ratio between thickness reduction Δd and thickness d1 can be between about 5% and about 20%. In some embodiments, annealing process 1650 can also apply on dielectric layer 1425 and metal oxide 1525 on S/D epitaxial structures 125. For example, similar to the formation of silicate layer 1615, a silicate layer 1625 can be formed between dielectric layer 1425 and metal oxide 1525, and oxygen vacancies in dielectric layer 1425 can be reduced or removed, transforming SiOₓ in dielectric layer 1425 into SiO₂.

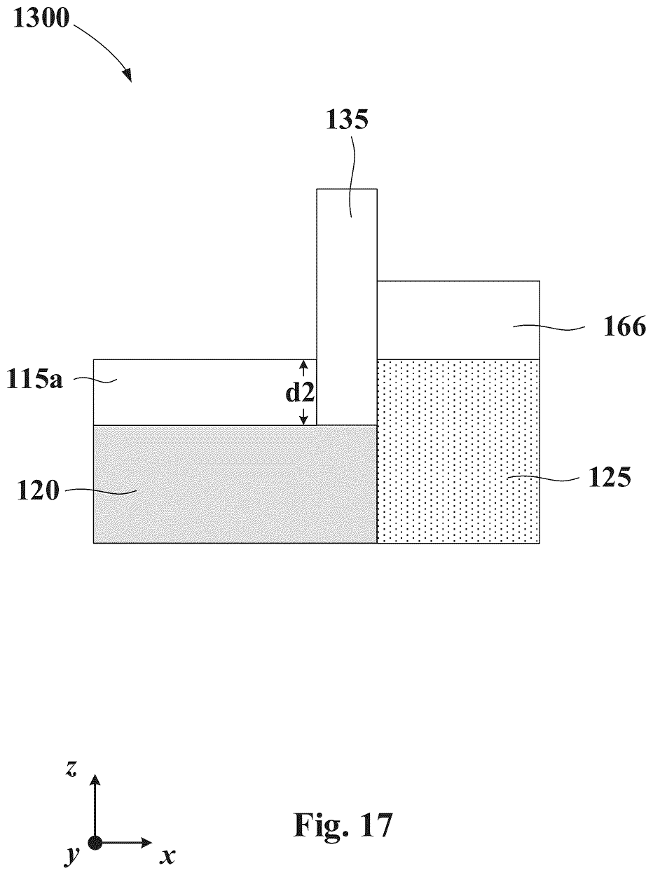

Referring to FIG. 4B, operation 440 continues with operation 448 and a process of removing the layer of metal oxide and the layer of silicate. For example, layers of metal oxide 1515 and 1525 and silicate layers 1615 and 1625 as shown in FIG. 16 can be removed, leaving IL 115a and dielectric layer 166 behind as described with reference to FIG. 17. In some embodiments, removing the layer of metal oxide and the layer of silicate can include performing a wet etching process in a chemical solution. In some embodiments, the chemical solution can include DI water, H2O2, HCl, DiCO2, or a combination thereof. For example, the chemical solution can include a mixture of H2O2, HCl, and DI water. In some embodiments, a temperature of the chemical solution can be at or above room temperature. For example, the temperature of the chemical solution can be about 50° C. In some embodiments, after the removal of the layer of silicate, there can be a small amount of the metal element (e.g., Y) remaining in IL 115a. In some embodiments, properties of IL 115a as shown in FIG. 17 and layer of SiOₓ 1415 as shown in FIG. 14 can be compared by XPS as shown in FIG. 3. After operations 442-448, IL 115a formed on NS layer 120 can have (i) its Si atoms in the Si⁴⁺ state with robust thermal stability and (ii) its thickness being scaled down.

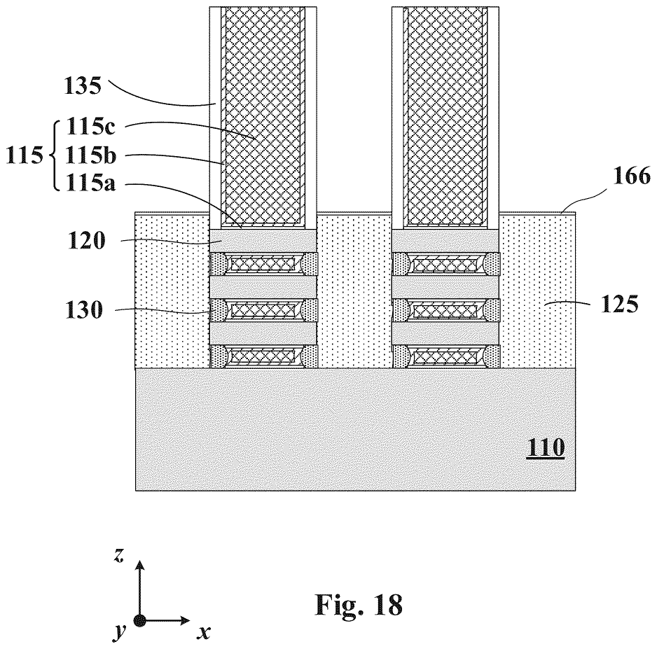

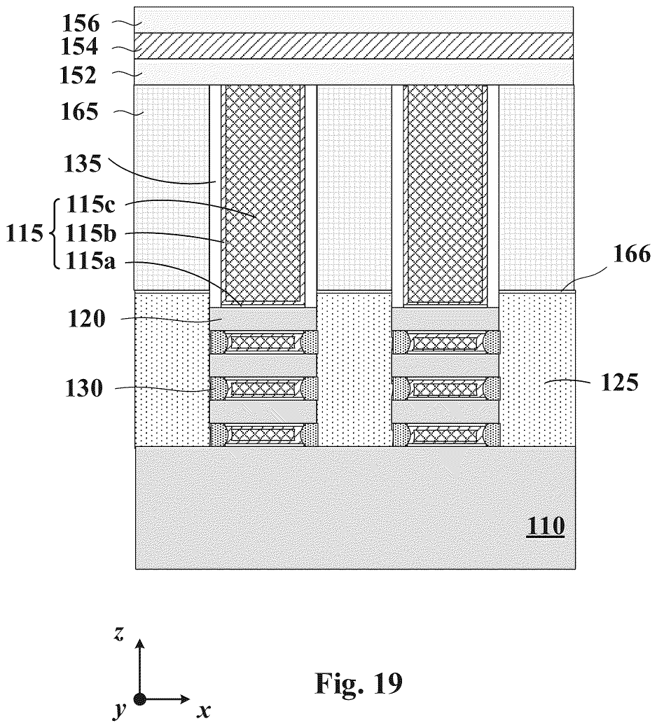

Referring to FIG. 4A, method 400 can continue with operation 450 and a process of depositing a gate dielectric layer on the IL and a gate electrode on the gate dielectric layer to form a metal gate structure. For example, as described with reference to FIG. 18, gate dielectric layer 115b can be deposited on IL 115a, and gate electrode 115c can be deposited on gate dielectric layer 115b to form metal gate structures 115. As discussed above, metal gate structures 115 are electrically isolated from S/D epitaxial structures 125 by inner spacer structures 130 and gate spacers 135. In some embodiments, depositing gate dielectric layer 115b can include depositing a high-k dielectric material (e.g., HfO₂, Al₂O₃, ScO₂, ZrO₂, CaO, MgO, and/or ZrSiO₄) in a CVD process or an ALD process. In some embodiments, depositing gate dielectric layer 115b can further include depositing a layer of lanthanum oxide (La₂O₃) to form N-dipoles in gate dielectric layer 115b for tuning the threshold voltage of transistors 105. In some embodiments, depositing gate electrode 115c can include depositing one or more work function metal layers and an electrode contact layer (e.g., titanium nitride, tantalum nitride, tungsten nitride, titanium, aluminum, copper, tungsten, tantalum, copper, or nickel) in a CVD process or an ALD process. In some embodiments, after forming metal gate structures 115, ILD layer 165 can be formed to fill the space above S/D epitaxial structures 125, as described with reference to FIG. 19. In some embodiments, one or more of dielectric layers 152, 154, and 156 can be formed over metal gate structures 115 and ILD layer 165 by sequential deposition of dielectric layers such as silicon oxide and silicon nitride, as described with reference to FIG. 19.

Referring to FIG. 4A, method 400 can continue with operation 460 and a process of forming contact structures on the gate electrode and the S/D region. For example, gate contact vias 167 can be formed on gate electrode 115c, and S/D contact 163 can be formed on S/D epitaxial structures 125, as described with reference to FIG. 2.

In some embodiments, forming gate contact vias 167 can include (i) forming an opening through one or more of dielectric layers 152, 154, and 156 to expose gate electrode 115c and (ii) depositing a metallic material (e.g., W, Cu, and/or Mo) in the opening.

In some embodiments, forming S/D contacts 163 can include (i) forming an opening through one or more of dielectric layers 152, 154, and 156 and though ILD layer 165 and dielectric layer 166 to expose S/D epitaxial structures 125, (ii) forming a silicide layer 164 on S/D epitaxial structures 125, and (iii) depositing a metallic material (e.g., W, Cu, and/or Mo) in the opening.

The embodiments described herein are directed to a structure of a semiconductor device and a method of forming the structure. The structure can include a transistor on a substrate. The transistor can include a channel region, a source/drain region adjacent to the channel region, and a gate structure on the channel region. The gate structure can include an IL on a surface of the channel region, a gate dielectric layer on the IL, and a gate electrode on the gate dielectric layer. The IL can include SiO₂ with a ratio of O atoms to Si atoms being about 2 and can be free of dangling bonds and oxygen vacancies. The method of forming the structure can include forming a SiOₓ layer on the channel region, depositing a metal oxide layer on the SiOₓ layer, performing an annealing process to promote oxygen atoms in the metal oxide layer to diffuse into the SiOₓ layer, such that oxygen vacancies in the SiOₓ layer can be reduced and removed. The annealing process can improve a quality of the IL by transforming the SiOₓ layer into a layer of SiO₂ layer. The method can further include removing the metal oxide layer and depositing the gate dielectric layer and the gate electrode on the IL to form the gate structure on the channel region.

In some embodiments, a method includes forming a channel region in a fin structure on a substrate, forming a source/drain (S/D) region adjacent to the channel region, forming an interfacial layer (IL) on the channel region, depositing a high-k dielectric layer on the IL, and depositing a gate electrode on the high-k dielectric layer. In some embodiments, forming the IL includes forming a layer of silicon oxide on the channel region, depositing a layer of yttrium oxide on the layer of silicon oxide, annealing the layer of yttrium oxide and the layer of silicon oxide to reduce a density of oxygen vacancies in the layer of silicon oxide, and removing the layer of yttrium oxide.

In some embodiments, a method includes forming a nanostructure in a fin structure, forming a source/drain (S/D) region adjacent to the nanostructure, and forming a gate structure surrounding the nanostructure. In some embodiments, forming the gate structure includes forming an interfacial layer (IL) on the nanostructure with the IL including oxygen and silicon, increasing a ratio of oxygen to silicon in the IL, depositing a high-k dielectric layer on the IL, and depositing a gate electrode on the high-k dielectric layer.

In some embodiments, a structure includes a substrate and a fin structure on the substrate, with the fin structure including a channel region. The structure further includes a source/drain (S/D) region on the fin structure and adjacent to the channel region and a gate structure surrounding the channel region. The gate structure includes an interfacial layer (IL) on the channel region, a high-k dielectric layer on the IL, a work function layer on the high-k dielectric layer, and a gate electrode on the work function layer. The IL includes silicon dioxide.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a channel region in a fin structure on a substrate;
forming a source/drain (S/D) region adjacent to the channel region;
forming an interfacial layer (IL) on the channel region, wherein forming the IL comprises:
forming a layer of silicon oxide on the channel region;
depositing a layer of yttrium oxide on the layer of silicon oxide;
annealing the layer of yttrium oxide and the layer of silicon oxide to reduce a density of oxygen vacancies in the layer of silicon oxide; and
removing the layer of yttrium oxide;
depositing a high-k dielectric layer on the IL; and
depositing a gate electrode on the high-k dielectric layer.

2. The method of claim 1, wherein annealing the layer of yttrium oxide and the layer of silicon oxide comprises forming a layer of silicate between the layer of yttrium oxide and the layer of silicon oxide.

3. The method of claim 2, wherein forming the IL further comprises removing the layer of silicate after removing the layer of yttrium oxide.

4. The method of claim 1, wherein annealing the layer of yttrium oxide and the layer of silicon oxide comprises transforming the layer of silicon oxide into a layer of silicon dioxide.

5. The method of claim 1, wherein annealing the layer of yttrium oxide and the layer of silicon oxide comprises increasing a ratio of oxygen to silicon in the IL.

6. The method of claim 1, wherein depositing the layer of yttrium oxide comprises depositing the layer of yttrium oxide by an atomic layer deposition process.

7. The method of claim 1, wherein forming the layer of silicon oxide comprises forming the layer of silicon oxide using a chemical solution of deionized water (DI-water), carbonated DI-water (DICO₂), ozonated DI-water (DIO₃), hydrogen peroxide (H₂O₂), sulfuric acid (H₂SO₄), chloric acid (HCl), or ammonia (NH₄OH).

8. A method, comprising:
forming a nanostructure in a fin structure;
forming a source/drain (S/D) region adjacent to the nanostructure; and
forming a gate structure surrounding the nanostructure, wherein forming the gate structure comprises:
forming, on the nanostructure, an interfacial layer (IL) comprising oxygen and silicon;
increasing a ratio of oxygen to silicon in the IL;
depositing a high-k dielectric layer on the IL; and
depositing a gate electrode on the high-k dielectric layer.

9. The method of claim 8, wherein increasing the ratio of oxygen to silicon in the IL comprises:
depositing a layer of yttrium oxide on the IL;
annealing the layer of yttrium oxide and the IL; and
removing the layer of yttrium oxide.

10. The method of claim 9, wherein annealing the layer of yttrium oxide and the IL comprises forming a layer of silicate between the layer of yttrium oxide and the IL.

11. The method of claim 8, wherein increasing the ratio of oxygen to silicon in the IL comprises reducing a thickness of the IL.

12. The method of claim 11, wherein reducing the thickness of the IL comprises reducing the thickness of the IL by about 5% to about 20%.

13. The method of claim 8, wherein increasing the ratio of oxygen to silicon in the IL comprises removing oxygen vacancies in the IL.

14. The method of claim 8, wherein increasing the ratio of oxygen to silicon in the IL comprises increasing the ratio of oxygen to silicon in the IL to about 2:1.

15. A structure, comprising:
a substrate;
a fin structure on the substrate, wherein the fin structure comprises a channel region;
a source/drain (S/D) region on the fin structure and adjacent to the channel region; and
a gate structure surrounding the channel region, wherein the gate structure comprises:
an interfacial layer (IL) on the channel region, wherein the IL comprises silicon dioxide, wherein a ratio of oxygen to silicon in the IL is about 2:1;
a high-k dielectric layer on the IL;
a work function layer on the high-k dielectric layer; and
a gate electrode on the work function layer.

16. The structure of claim 15, wherein the IL is in contact with top, bottom, and side surfaces of the channel region.

17. The structure of claim 15, wherein a thickness of the IL is about 1 nm.

18. The structure of claim 15, wherein the IL comprises yttrium, scandium, lanthanum, zinc, or lutetium.

19. The structure of claim 15, further comprising an oxide layer on the S/D region, wherein thicknesses of the oxide layer and the IL are substantially the same.

20. The structure of claim 15, further comprising an oxide layer on the S/D region, wherein another ratio of oxygen to silicon in the oxide layer is about 2:1.
